(19) United States
(12) Patent Application Publication
(10) Pub. No.: US 2016/0225823 A1
(43) Pub. Date: Aug. 4, 2016

(54) SWITCHING RESISTANCE MEMORY DEVICES WITH INTERFACIAL CHANNELS

(71) Applicant: Hewlett Packard Enterprise Development LP, Houston, TX (US)

(72) Inventors: Shih-Yuan Wang, Palo Alto, CA (US); Jianhua Yang, Palo Alto, CA (US); R. Stanley Williams, Palo Alto, CA (US)

(21) Appl. No.: 14/916,766

(22) PCT Filed: Sep. 16, 2013
(86) PCT No.: PCT/US2013/059935

§ 371 Date: Mar. 4, 2016

(51) Int. Cl. H01L 27/24; H01L 45/00

(52) U.S. Cl. CPC H01L 27/2463; H01L 45/085; H01L 45/1226; H01L 45/1266; H01L 45/146; H01L 45/1616

(57) ABSTRACT

A switching resistance memory device with an interfacial channel includes a stack made of a layer of a first material and a layer of a second material. The layers form an interface, with the interface comprising the interfacial channel along which charged species can travel. A first electrode contacts a first edge of the stack, and a second electrode contacts a second edge of the stack.

### BACKGROUND

Resistance memory elements can be programmed to different resistance states by applying programming energy. After programming, the state of the resistive memory elements can be read and remains stable over a specified time period. Large arrays of resistive memory elements can be used to create a variety of resistive memory devices, including non-volatile solid state memory, programmable logic, signal processing, control systems, pattern recognition devices, and other applications. Examples of resistive memory devices include valence change memory and electrochemical metallization memory, both of which involve ionic motion during electrical switching and belong to the category of memristors.

Memristors are devices that can be programmed to different resistive states by applying a programming energy, for example, a voltage or current pulse. This energy generates a combination of electric field and thermal effects that can modulate the conductivity of both non-volatile switch and non-linear select functions in a memristive element. After programming, the state of the memristor can be read and remains stable over a specified time period.

### BRIEF DESCRIPTION OF THE DRAWINGS

FIG. 1 is a cross-sectional view of an interface switching resistive memory device having a bi-layer structure that includes a heterostructure junction, according to an example.

FIG. 2 is a cross-sectional view of another interface switching resistive memory device having a multi-layer structure that includes a plurality of heterostructure junctions, according to an example.

FIG. 3 is a cross-sectional view of yet another interface switching resistive memory device, in which the layers are arranged in a vertical configuration, according to an example.

FIG. 4A is a cross-sectional view of a structure used to study interface effects in a device similar to that depicted in FIG. 1, but omitting one layer of the bi-layer structure, according to an example.

FIG. 4B, on coordinates of current (A) and voltage (V), is a plot of the I-V characteristics of the device of FIG. 4A, showing repeatable switching.

FIG. 5 is a flow chart depicting a method for making an interface switching resistive memory device, such as a memristor, according to an example.

FIG. 6 is an isometric view of a crossbar architecture incorporating resistive memory devices such as shown in the foregoing Figures, particularly FIG. 3, according to an example.

### DETAILED DESCRIPTION

In the following description, numerous details are set forth to provide an understanding of the examples disclosed herein. However, it will be understood that the examples may be practiced without these details. While a limited number of examples have been disclosed, it should be understood that there are numerous modifications and variations therefrom. Similar or equal elements in the Figures may be indicated using the same numeral.

As used in the specification and claims herein, the singular forms “a,” “an,” and “the” include plural referents unless the context clearly dictates otherwise.

As used in this specification and the appended claims, “approximately” and “about” mean a ±10% variance caused by, for example, variations in manufacturing processes.

In the following detailed description, reference is made to the drawings accompanying this disclosure, which illustrate specific examples in which this disclosure may be practiced. The components of the examples can be positioned in a number of different orientations and any directional terminology used in relation to the orientation of the components is used for purposes of illustration and is in no way limiting. Directional terminology includes words such as “top,” “bottom,” “front,” “back,” “leading,” “trailing,” etc.

It is to be understood that other examples in which this disclosure is may be practiced exist, and structural or logical changes may be made without departing from the scope of the present disclosure. Therefore, the following detailed description is not to be taken in a limiting sense. Instead, the scope of the present disclosure is defined by the appended claims.

Resistive memory elements can be used in a variety of applications, including non-volatile solid state memory, programmable logic, signal processing, control systems, pattern recognition, and other applications.

As used in the specification and appended claims, the term “resistance memory elements” refers broadly to programmable non-volatile resistors where the switching mechanism involves atomic motion, including valance change memory, electrochemical metallization memory, and others.

Memristors, or memristive devices, are nano-scale devices that may be used as a component in a wide range of electronic circuits, such as memories, switches, and logic circuits and systems. In a memory structure, a crossbar of memristors may be used. For example, when used as a basis for memories, the memristor may be used to store a bit of information, 1 or 0, corresponding to whether the memristor is in its high or low resistance state (or vice versa). When used as a logic circuit, the memristor may be employed as configuration bits and switches in a logic circuit that resembles a Field Programmable Gate Array, or may be the basis for a wired-logic Programmable Logic Array. It is also possible to use memristors capable of multi-state or analog behavior for these and other applications.

When used as a switch, the memristor may either be in a low resistance (closed) or high resistance (open) state in a cross-point memory. During the last few years, researchers have made great progress in finding ways to make the switching function of these memristors behave efficiently. For example, tantalum oxide (TaOₓ)-based memristors have been demonstrated to have superior endurance over other nano-scale devices capable of electronic switching. In lab settings, tantalum oxide-based memristors are capable of over 10 billion switching cycles.

A memristor may comprise a switching material, such as TiOₓ or TaOₓ, sandwiched between two electrodes. Memristive behavior is achieved by the movement of ionic species (e.g., oxygen ions or vacancies) within the switching material to create localized changes in conductivity via modulation of a conductive filament between two electrodes, which results in a low resistance “ON” state, a high resistance “OFF” state, or intermediate states, Initially, when the memristor is first fabricated, the entire switching material may be nonconductive. As such, a forming process may be required to form the conductive channel in the switching material between the two electrodes. A known forming process, often called “electroforming”, includes applying a sufficiently high (threshold) voltage across the electrodes for a sufficient length of time to cause a nucleation and formation of a localized conductive channel (or active region) in the switching material. The threshold voltage and the length of time required for the forming process may depend upon the type of material used for the switching material, the first electrode, and the second electrode, and the device geometry.

Metal or semiconductor oxides may be employed in memristive devices; examples include either transition metal oxides, such as tantalum oxide, titanium oxide, yttrium oxide, hafnium oxide, niobium oxide, zirconium oxide, or other like oxides, or non-transition metal oxides, such as aluminum oxide, calcium oxide, magnesium oxide, dysprosium oxide, lanthanum oxide, silicon dioxide, or other like oxides. Further examples include transition metal nitrides, such as aluminum nitride, gallium nitride, tantalum nitride, and silicon nitride.

Memristive devices may include a continuous oxide film between the electrodes. Filaments/ionic diffusion are formed in the oxide film between the electrodes in a random fashion, much like lightning, that may take the path of least resistance. This random path causes variations in the memristor I-V characteristics from switching cycle to cycle and especially from device to device. Older memristive or non-volatile resistive memory devices that are either unipolar or bipolar tend to have this random conductive path between the electrodes; that is, the vacancies have to find their own path to the opposite electrodes. This randomness in the conductive channel formation may cause variability in reproducibility and/or reliability issues, which is one of the biggest challenges in the commercialization of these devices.

In accordance with the teachings herein, a resistive memory structure is provided that causes vacancies to travel along an interface of a heterojunction metal oxide and/or nitride layer to improve the variability and performance of the device. By providing a vacancy “highway” along the interface of the heterostructure, the vacancies can easily move to the opposing electrode. As an example, the vacancies can move along the heterojunction at rates of up to 10³ to 10⁴ times faster than in bulk. The fast vacancy movement reduces the switching energy and makes the interface a natural conduction channel, thereby reducing variability from device to device and from switching cycle to cycle.

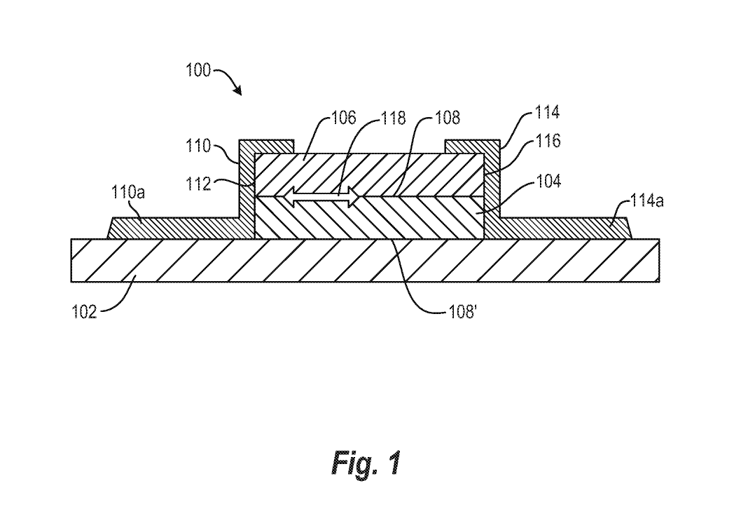

FIG. 1 depicts an example of such a structure. In this case, a resistive memory device 100, in particular, a memristor, is formed on an insulating substrate 102. The device 100 includes a first layer 104 and a second layer 106, with a junction, or interface, 108 between the two layers. A first electrode 110 contacts a first side 112 of the structure and a second electrode 114 contacts a second, opposite side 116 of the structure. A portion of each electrode extends over the substrate 102 to form contact pads 110a, 114a, The electrodes 110, 114 contact opposite ends of the interface 108. Vacancy movement from the first electrode 110 to the second electrode 114 along interface 108 is indicated by double headed arrow 118; this movement may occur upon application of a voltage between the two electrodes. It will be appreciated that vacancy movement may also occur along the interface 108′ formed between layer 104 and the substrate 102. In general, the rate of movement along interface 108′ may be slower than the rate of movement along interface 108, and thus, vacancy movement along interface 108 may dominate, depending on the materials involved. The interface 108 becomes an interfacial channel along which charged species, such as vacancies, can travel.

The electrodes 110, 114 may be formed to bend over the top of the uppermost layer 106 as shown here or may terminate on the side of the uppermost layer (not shown). The relative ease of forming one configuration or the other during manufacturing may dictate which configuration is employed.

Examples of insulating substrate 102 include, but are not limited to, oxides, such as quartz, silicon oxide, aluminum oxide, magnesium oxide, calcium oxide; ternary oxides, such as strontium titanate and lanthanum aluminate; nitrides, such as silicon nitride and aluminum nitride; and undoped semiconductors, such as undoped silicon. The substrate 102 may be more resistive than first layer 104 formed on it. In some examples, the substrate 102 may be at least two times more resistive than the first layer 104. In one example, the insulating substrate 102 is quartz.

Examples of the two layers 104 and 106 have been given above as transition and non-transition metal oxides and nitrides. However, these oxides and nitrides may not be “full” (stoichiometric) oxides, but rather defect oxides. The deficiency in oxygen (or nitrogen) may create oxygen (or nitrogen) vacancies, which then may move along the interface(s) 108 under application of an electric field. In one example, the first layer 104 is HfOₓ or TiOₓ, where x is greater than 1 and less than 2 (1<x<2), while the second layer 106 is TaOₓ, where x is greater than 2 and less than 2.5 (2<x<2.5). The thickness of layers 104 and 106 may each range from about 2 to 100 nm, independent of the other.

The interface 108 formed between the two layers 104, 106 supports the vacancy movement. The interface may be achieved by using two different materials to form the two layers 104, 106, such as HfOₓ and TaOₓ. Alternatively, the interface may be achieved by using two different crystallographic structures of the same material. An example may be an amorphous material forming one of the two layers 104, 106 and a crystalline material forming the other of the two layers 106, 104. The two layers may have different thickness. In case that one material has a higher resistivity than the other, the more resistive one may be thinner than the less resistive one so that the resistances of the two layers are similar.

The two layers 104, 106 may be placed in alternating configuration. Either layer 104, 106 may be formed on the substrate 102 first. The number of layers may be the same or different. For example, there may be four layers 104 and four layers 106. Or, there may be four layers 104 and three (or five) layers 106, or vice versa.

The two electrodes 110, 114 may be formed on substrate 102 and the sides 112, 116 of the two layers 104, 106 by any of a number of processes, including electroplating, sputtering, evaporation, ALD (atomic layer deposition), co-deposition, chemical vapor deposition, IBAD (ion beam assisted deposition), oxidation of pre-deposited materials, or any other film deposition technology. Examples of materials for electrodes 110, 114 include, but are not limited to, aluminum (Al), copper (Cu), platinum (Pt), tungsten (W), gold (Au), titanium (Ti), silver (Ag), ruthenium dioxide (RuO₂), titanium nitride (TiN), tungsten nitride (WN₂). tantalum (Ta), tantalum nitride (TaN) or the like. The electrode materials may be the same or different for the two electrodes. The electrodes 110, 114 may be patterned, if desired. The thickness of the electrodes 110, 114 may be in the range of about 10 nm to a few micrometers.

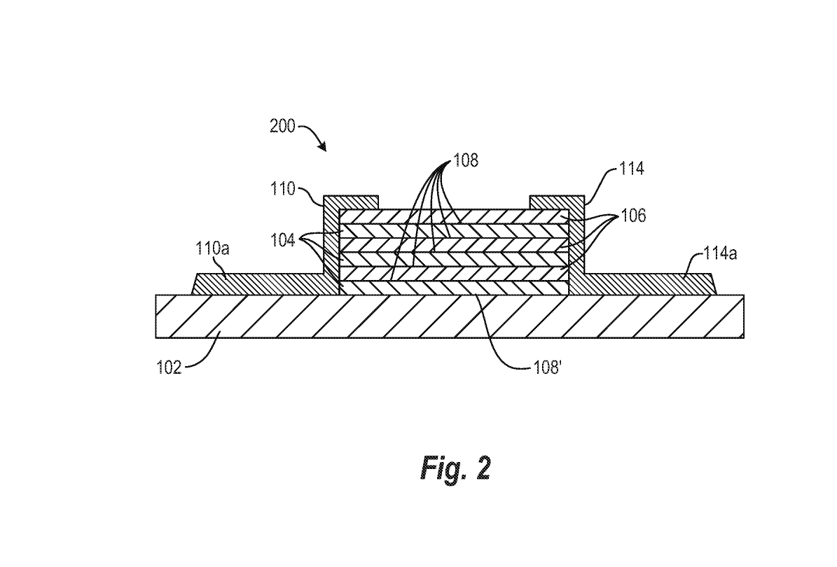

The foregoing example is directed to one interface 108 in a device. Alternatively, there may be a plurality of interfaces 108 in the device structure. FIG. 2 illustrates a stack of three bi-layers, with a total of five interfaces 108. In this example, the resistive memory device 200 consists of alternating layers of three first layers 104 and three second layers 106, separated by interfaces 108. Oxygen vacancies can travel along all five interfaces 108.

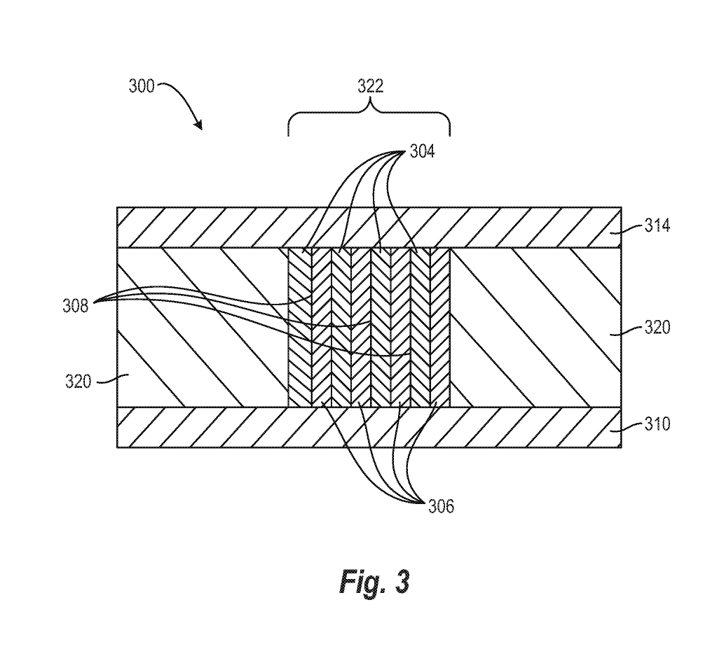

FIG. 3 depicts an alternate device structure 300, which is a vertical switching resistance memory device, or, more specifically, a memristor. The device 300 may include bottom electrode 310 and top electrode 314. Layers 304, 306 may be vertically disposed, in alternating fashion, between the two electrodes 310, 314. The device 300 may be supported on a substrate (not shown). A dielectric material 320 may be disposed on either side of the vertically-disposed stack 322 formed by the two layers 304, 306. Vacancies are able to travel along interfaces 308 formed between the two layers 304, 306. The dielectric material may serve to provide support for the top electrode 314 as well as provide electrical isolation between adjacent vertically-disposed stacks 322.

The structure 300 depicted in FIG. 3 may be formed by a number of processes. For example, ALD (atomic layer deposition) may be used to form the vertical layers 304, 306, one layer at a time through a hole in the insulating layer 320. Multiple chemical-mechanical polishing (CMP) and regrowth of switching layers 104, 106 may be employed to form the stack 322 of alternating layers.

In another example, nanowires of a first oxide may be grown side by side and then covered with a coating of the second oxide.

In yet another example, the layers 304, 306 may be grown horizontally on a substrate, separated from the substrate, and then rotated 90 degrees and affixed to the bottom electrode 310. The insulating oxide 320 may be grown and the top electrode formed on the insulating oxide and the exposed edge of the vertically-disposed stack 322.

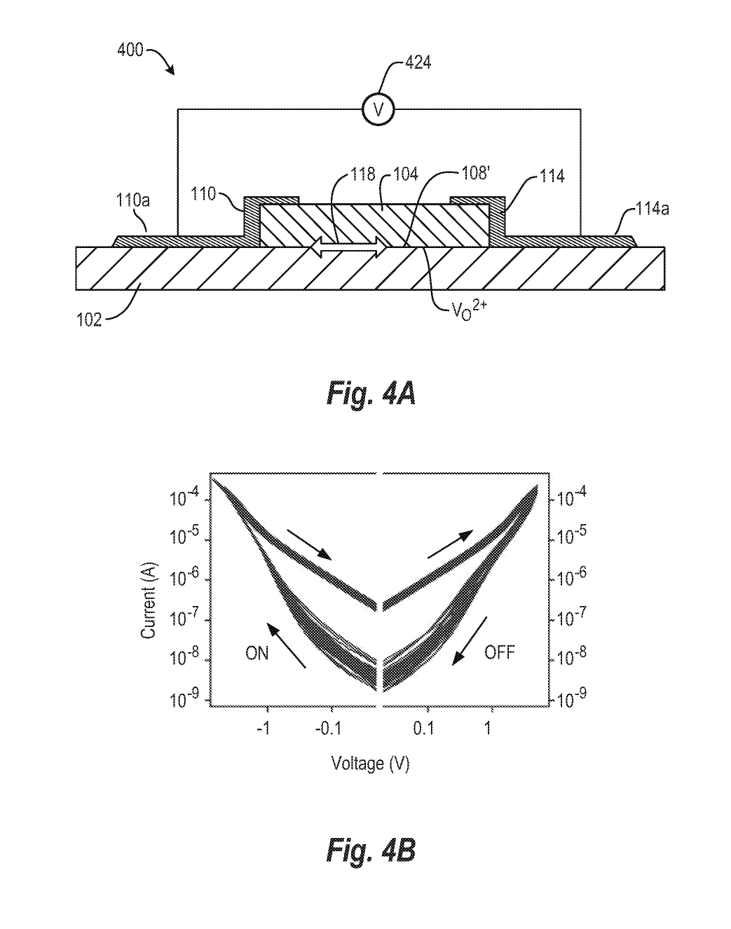

FIG. 4A depicts an example of a structure 400 used to study interface effects in a device similar to that depicted in FIG. 1, but omitting one layer of the bi-layer structure. In this example, the substrate was quartz, the two electrodes 110, 114 were platinum, and layer 104 was TiOₓ, where x was about 2 (1.9<x<2).

A voltage source 424 was electrically connected between electrodes 110 and 114 via contact pads 110a and 114a. In this example, switching the device 400 ON may be performed by application of a negative voltage, while switching the device OFF may be performed by application of a positive voltage. In other situations, the reverse may be true.

Here, oxygen vacancies move along the interface 108′, which is formed between layer 104 (TiOₓ) and the substrate 102 (quartz). The oxygen is vacancy movement (V_{O}²) along the interface formed by TiOₓ/quartz faster than in the bulk of TiO₂ or quartz. The faster movement will dominate the movement of charge from one electrode 110, 114 to the other 114, 110.

FIG. 4B, on coordinates of current (A) and voltage (V), is a plot of the I-V characteristics of the device of FIG. 4A, showing repeatable switching. As noted above, ON switching takes place with application of a negative voltage; OFF switching takes place with application of a positive voltage. The switching is performed over a number of cycles, alternating between negative and positive voltage.

The plot shows good reproducibility over 50 switching cycles. The bands would be wider if the reproducibility were not good. Consequently, the structure 400 exhibits repeatability and relatively low energy, as shown by the current level.

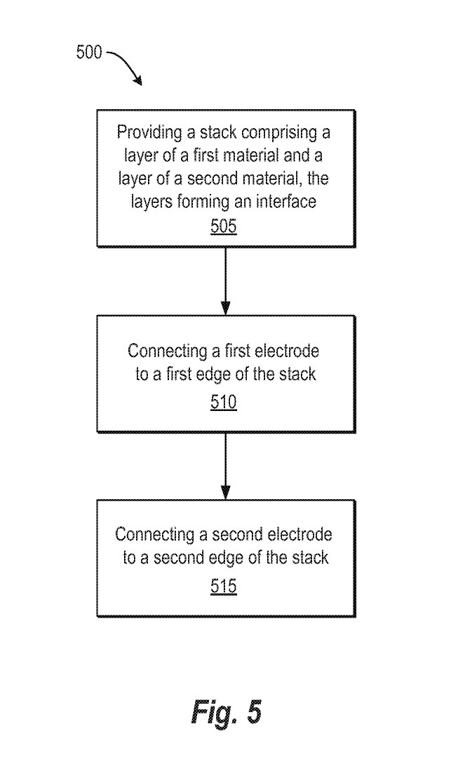

An example method 500 for the formation of the interface switching resistive memory device 100, 200, 300 is shown in FIG. 5. The stack 322 is first formed 505. The stack 322 may comprise one or more of layer(s) 104, 304 and one or more of layer(s) 106 306, arranged in alternating fashion, to form at least one interface 108, 308.

A first electrode 110, 310 is connected 510 to a first edge 112 of the stack 322, and a second electrode 114, 314 is connected 515 to a second edge 116 of the stack 322. The layers 104, 106 may be supported on a substrate 102 and horizontally aligned with the substrate, as shown in FIGS. 1 and 2, with the electrodes 110 and 114 connected to the edges. Alternatively, the layers 304, 306 may be sandwiched between the two electrodes 310, 314 and vertically aligned with respect to the two electrodes, as shown in FIG. 3.

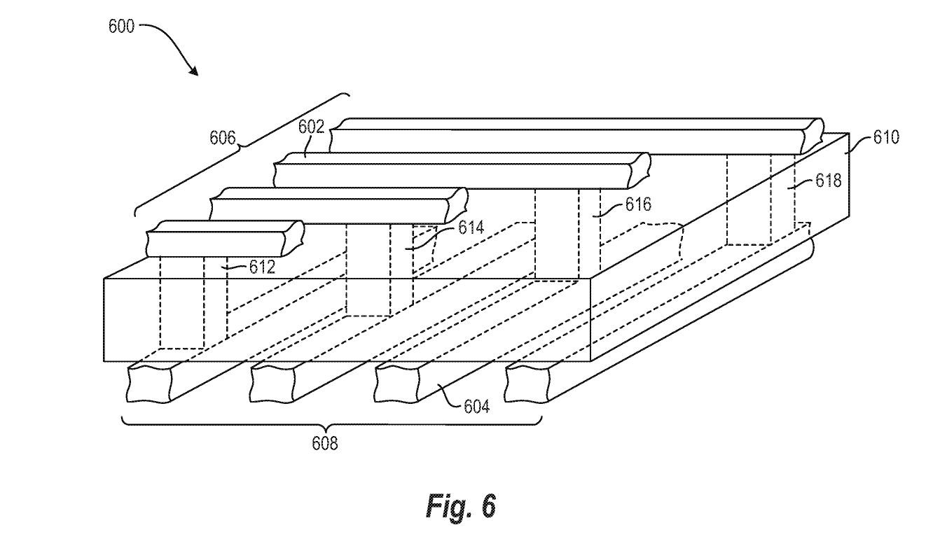

The devices 100, 200 depicted in FIGS. 1 and 2 may find application in non-crossbars, where density is not critical, but repeatability and energy are. On the other hand, the device 300 depicted in FIG. 3 may find application in crossbars. FIG. 6 illustrates a perspective view of a nanowire memory array, or crossbar, 600, revealing an intermediate layer 610 disposed between a first layer of approximately parallel nanowires 608 and a second layer of approximately parallel nanowires 606. The first layer of nanowires may be at a non-zero angle relative to the second layer of nanowires.

According to one illustrative example, the intermediate layer 610 may be a dielectric layer, such as insulating layer 320. A number of the resistance memory devices 612-618 may be formed at the intersections, or junctions, between nanowires 602 in the top layer 606 and nanowires 604 in the bottom layer 608. The nanowires 602, 604 may serve as the top and bottom electrodes 314, 310, respectively, in the resistance memory device 300. For example, when forming a resistance memory device similar to the example shown in FIG. 3, the nanowires in the top layer 606 may be formed from a conductive material, such as copper, aluminum, or the like, and the nanowires in the bottom layer 608 may be formed from the conductive material, which may be the same or different as the top layer 606. The upper nanowires would then serve as the top electrode 314 and the lower nanowires would serve as the bottom electrode 310.

To avoid complicating FIG. 6, the individual layers 304, 306 are not shown, but the stack 322 is shown.

For purposes of illustration, only a few of the resistance memory devices 612-618 are shown in FIG. 6. Each of the combined devices 612-618 may be used to represent one or more bits of data. For example, in the simplest case, a resistance device may have two states: a conductive state and a non-conductive state. The conductive state may represent a binary “1” and the non-conductive state may represent a binary “0”, or vice versa. Binary data may be written into the nanowire memory array 600 by changing the conductive state of the matrix within the resistive memory devices. The binary data can then be retrieved by sensing the conductive state of the resistive memory devices 612-618.

The example above is only one illustrative example of the memory array 600. A variety of other configurations may be used. For example, the memory array 600 may incorporate nonlinear elements that have different structures. The different structures may include more or less layers, layers that have different compositions than described above, and layers that are ordered in different ways than shown in the example given above. For example, the memory array may include memristors or other memory elements. Further, the memory array may use a wide range of conductors to form the crossbars.

It should be understood that the resistance memory devices, and memristors, described herein, such as the example memristors depicted in the Figures, may include additional components and that some of the components described herein may be removed and/or modified without departing from the scope of the resistance memory device disclosed herein. It should also be understood that the components depicted in the Figures are not drawn to scale and thus, the components may have different relative sizes with respect to each other than as shown therein. For example, the upper, or second, electrode 314 may be arranged substantially perpendicularly to the lower, or first, electrode 310 or may be arranged at some other non-zero angle with respect to each other. Further, deposited layers may or may not be conformal with respect to underlying features.

What is claimed is:

1. A switching resistance memory device with an interfacial channel, including:
a stack comprising a layer of a first material and a layer of a second material, the layers forming an interface, the interface comprising the interfacial channel along which charged species can travel;
a first electrode contacting a first edge of the stack; and
a second electrode contacting a second edge of the stack.

2. The switching resistance memory device of claim 1, wherein the device is a switching memristor with the interfacial channel.

3. The switching resistance memory device of claim 1, wherein the stack is disposed on an insulating substrate and the layers are disposed parallel to the substrate.

4. The switching resistance memory device of claim 3, wherein the first electrode contacts the first edge of the stack and the second electrode contacts the second edge of the stack, and wherein each electrode includes a contact portion supported on the substrate.

5. The switching resistance memory device of claim 1, wherein the stack is disposed on the first electrode and the layers are disposed vertically to the first electrode so that the first electrode contacts the first edge of the stack.

6. The switching resistance memory device of claim 5, wherein the second electrode contacts the second edge of the stack, with an insulating material disposed between the first electrode and the second electrode.

7. The switching resistance memory device of claim 1, wherein the stack comprises a plurality of layers, arranged in alternating configuration, the layers forming a plurality of interfaces.

8. The switching resistance memory device of claim 1, wherein the first material and the second material are each selected from the group consisting of defect transition metal oxides, defect non-transition metal oxides, and defect transition metal nitrides, wherein the first material and the second material are different.

9. The switching resistance memory device of claim 8, wherein the transition metal oxides are selected from the group consisting of tantalum oxide, titanium oxide, yttrium oxide, hafnium oxide, niobium oxide, and zirconium oxide, wherein the non-transition metal oxides are selected from the group consisting of aluminum oxide, calcium oxide, magnesium oxide, dysprosium oxide, lanthanum oxide, and silicon dioxide, and wherein the transition metal nitrides are selected from the group consisting of aluminum nitride, gallium nitride, tantalum nitride, and silicon nitride.

10. A crossbar comprising an array of approximately first nanowires and an array of approximately second nanowires, the array of first nanowires crossing the array of second nanowires at a non-zero angle, each intersection of a first nanowire with a second nanowire forming a junction, with the switching resistance memory device of claim 1 at each junction, sandwiched between a first nanowire and a second nanowire.

11. A method for making a switching resistance memory device, including:
providing a stack comprising a layer of a first material and a layer of a second material, the layers forming an interface, the interface comprising the interfacial channel along which charged species can travel;
connecting a first electrode to a first edge of the stack; and
connecting a second electrode to a second edge of the stack.

12. The method of claim 11, wherein the device is a switching memristor with the interfacial channel.

13. The method of claim 11 wherein the stack is formed on an insulating substrate and the layers are formed parallel to the substrate, with the first electrode being formed to contact the first edge of the stack and the second electrode being formed to contact the second edge of the stack, and wherein each electrode includes a contact portion supported on the substrate.

14. The method of claim 11, wherein the stack is formed on the first electrode and the layers are formed vertically to the first electrode so that the first electrode contacts the first edge of the stack and wherein the second electrode is formed to contact the second edge of the stack, with an insulating material formed between the first electrode and the second electrode.

15. The method of claim 11, wherein the stack comprises a plurality of layers, arranged in alternating configuration, the layers forming a plurality of interfaces.
